(19) United States
(12) Patent Application Publication
(10) Pub. No.: US 2025/0106996 A1
(43) Pub. Date: Mar. 27, 2025

(54) ELECTRONIC ASSEMBLY

(71) Applicant: VIA Technologies, Inc., New Taipei City (TW)

(72) Inventors: Nai-Shung Chang, New Taipei City (TW); Ping-Hsun Hsieh, New Taipei City (TW); Hung-Sen Liang, New Taipei City (TW)

(73) Assignee: VIA Technologies, Inc., New Taipei City (TW)

(21) Appl. No.: 18/811,795

(22) Filed: Aug. 22, 2024

Related U.S. Application Data
(60) Provisional application No. 63/540,917, filed on Sep. 27, 2023.

(30) Foreign Application Priority Data
Jun. 25, 2024 (TW) 113123597

(51) Int. Cl. H05K 1/11; H05K 1/02; H05K 1/18

(52) U.S. Cl. CPC H05K 1/111; H05K 1/0213; H05K 1/181

(57) ABSTRACT

An electronic assembly includes a circuit board having a mounting surface and outer pads located on the mounting surface and staggered. The outer pads include pairs of differential signal pads arranged adjacent to each other including a first pair of differential signal pads and a second pair of differential signal pads. The first pair of differential signal pads and the second pair of differential signal pads are symmetrically arranged with respect to a symmetry line. A center extension line passing through the first pair of differential signal pads and a center extension line passing through the second pair of differential signal pads intersect at an intersection point on the symmetry line. The center extension line passing through the first pair of differential signal pads or the center extension line passing through the second pair of differential signal pads and the symmetry line are not perpendicular to each other.

### CROSS-REFERENCE TO RELATED APPLICATION

This application claims the priority benefit of U.S. Provisional Application No. 63/540,917, filed on Sep. 27, 2023 and Taiwan Application No. 113123597, filed on Jun. 25, 2024. The entirety of each of the above-mentioned patent applications is hereby incorporated by reference herein and made a part of this specification.

### BACKGROUND

### Technical Field

The disclosure relates to an electronic assembly, and in particular, relates to an electronic assembly including a circuit board having a layout for differential signal transmission.

### Description of Related Art

Differential signal transmission is a signal transmission technology. Compared to conventional single-ended signal transmission with one signal line and one ground line, differential signal transmission transmits two signals at a time on a pair of signal lines (i.e., a pair of signal transmission paths), and the two signals have the same amplitude and opposite phase. The signals transmitted on this pair of signal lines are differential signals. Compared with single-ended signals, differential signals have improved anti-interference capabilities, can effectively suppress electromagnetic interference (EMI), and have accurate timing positioning. Therefore, differential signals are usually used for high-speed signal transmission.

### SUMMARY

The disclosure provides an electronic assembly having a circuit board configured to provide a layout for differential signal transmission.

The disclosure provides an electronic assembly including a circuit board. The circuit board has a mounting surface and a plurality of outer pads located on the mounting surface and staggered. The outer pads include a plurality of pairs of differential signal pads arranged adjacent to each other. The pairs of differential signal pads include a first pair of differential signal pads and a second pair of differential signal pads. The first pair of differential signal pads and the second pair of differential signal pads are symmetrically arranged with respect to a symmetry line. A center extension line passing through the first pair of differential signal pads and a center extension line passing through the second pair of differential signal pads intersect at an intersection point on the symmetry line. Further, the center extension line passing through the first pair of differential signal pads or the center extension line passing through the second pair of differential signal pads and the symmetry line are not perpendicular to each other.

To sum up, in the disclosure, the circuit board may provide a layout for differential signal transmission, and the center extension lines of two adjacent pairs of differential signal pads are inclined and intersect each other.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic side view of a portion of a circuit board of an electronic assembly according to an embodiment of the disclosure.

FIG. 2A is a schematic top view of a first pad group and a second pad group of an outer circuit layer of the circuit board of FIG. 1.

FIG. 2B is a schematic view of portions of five patterned conductive layers near a mounting surface of the circuit board of FIG. 1.

FIG. 3 is a schematic top view of a portion of a first inner circuit layer and a portion of a second inner circuit layer of FIG. 2B.

FIG. 4 is a schematic top view of a portion of the outer circuit layer of the circuit board of FIG. 1.

FIG. 5 is a schematic top view of a portion of the first inner circuit layer of the circuit board of FIG. 1.

FIG. 6 is a schematic top view of a portion of the second inner circuit layer of the circuit board of FIG. 1.

FIG. 7 is a schematic top view of the outer circuit layer of the circuit board of the electronic assembly according to another embodiment of the disclosure.

FIG. 8 is a schematic side view of the electronic assembly according to another embodiment of the disclosure.

FIG. 9 is a schematic side view of the electronic assembly according to another embodiment of the disclosure.

### DESCRIPTION OF THE EMBODIMENTS

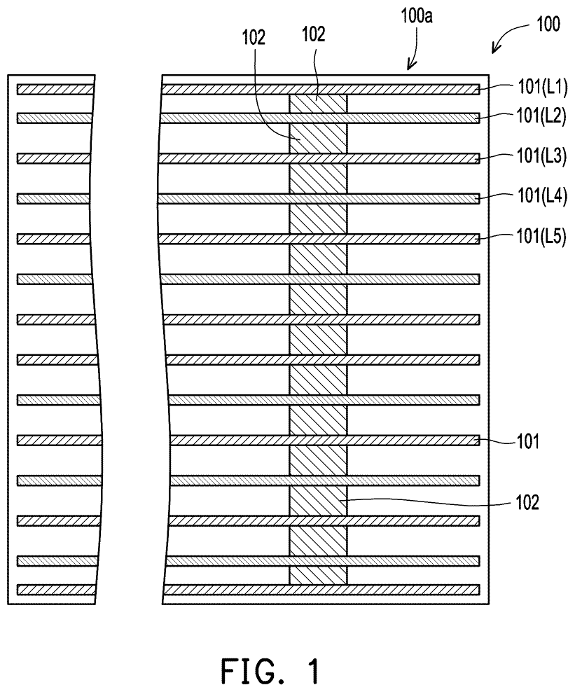

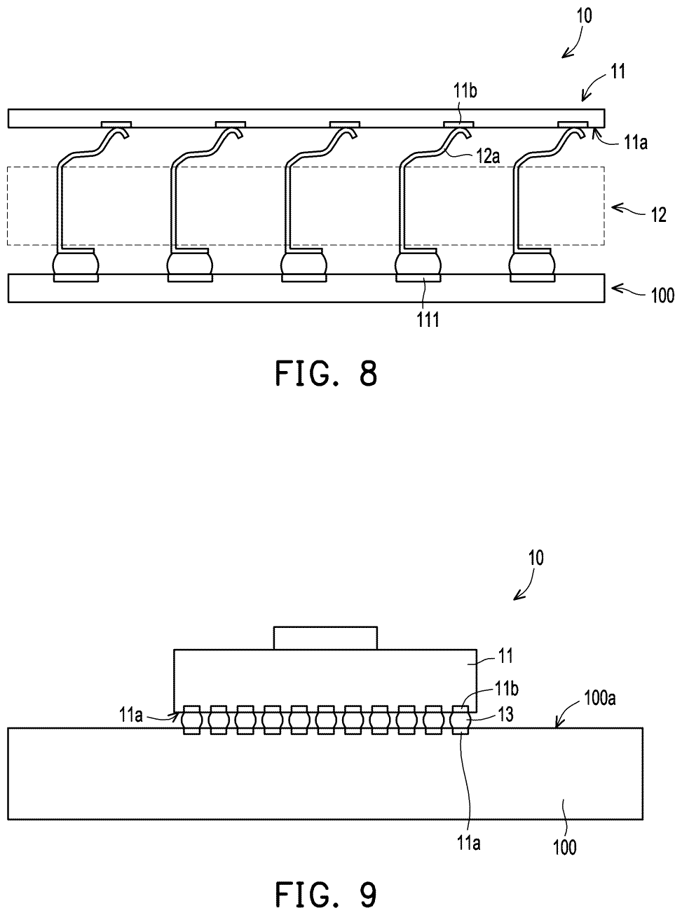

With reference to FIG. 1, in this embodiment, a circuit board 100 may provide a signal transmission path and may be used as one of the components of an electronic assembly 10 (e.g., the electronic assembly 10 shown in FIG. 8 or FIG. 9).

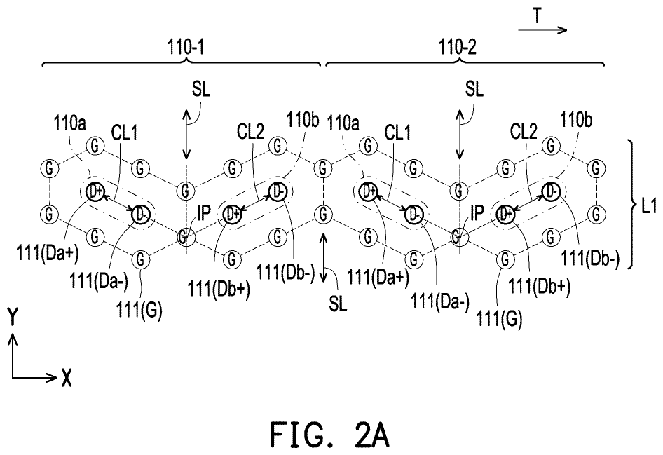

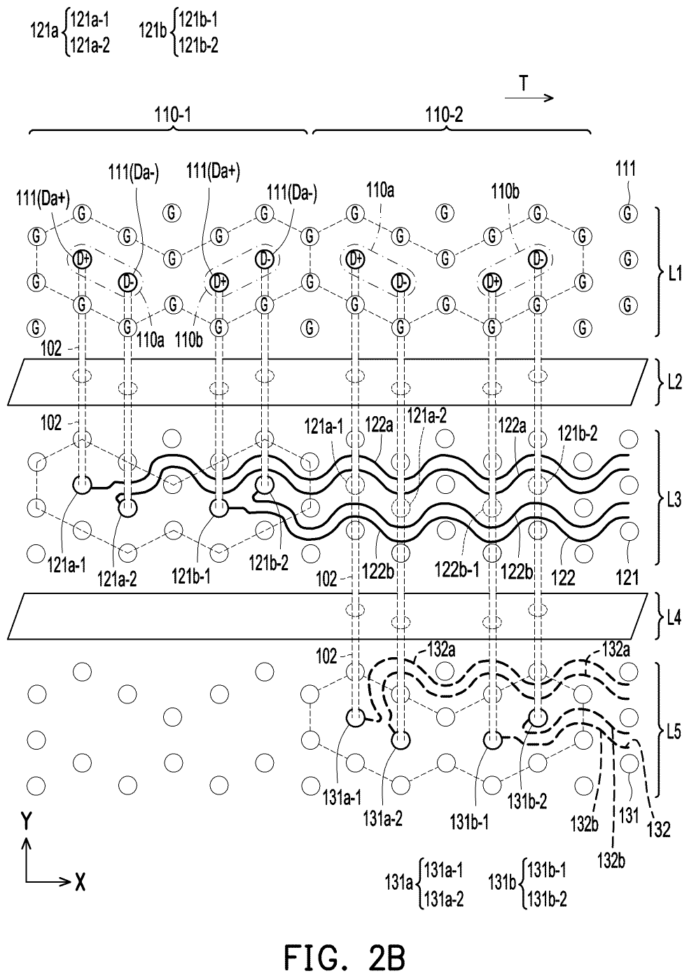

With reference to FIG. 1, FIG. 2A and FIG. 2B, in this embodiment, the circuit board 100 has a mounting surface 100a and a plurality of outer pads 111 located on the mounting surface 100a and are staggered. The word “staggered” means that projections of the outer pads 111 in two adjacent columns (i.e., vertical columns) on the Y axis do not overlap, and projections of the outer pads 111 in two adjacent rows (i.e., horizontal rows) on the X axis do not overlap. Further, eighteen outer pads 111 may are grouped into a pad group, such as a first pad group 110-1 and a second pad group 110-2 as shown in FIG. 2A. The outer pads 111 include a plurality of pairs of differential signal pads 111 (D+/D−) arranged adjacent to each other. The outer pads 111 are in a form of, for example, a land grid array (LGA). The pairs of differential signal pads 111 (D+/D−) include a first pair of differential signal pads 110a and a second pair of differential signal pads 110b, which are arranged in the manner shown in FIG. 2A. To be specific, the first pair of differential signal pads 110a includes two adjacent differential signal pads Da+ and Da−, and the differential signal pads Da+ and Da− are located in different columns and rows. In other words, the projections of the two adjacent differential signal pads Da+ and Da− on the X-axis or Y-axis do not overlap. The second pair of differential signal pads 110b includes two adjacent differential signal pads Db+ and Db−, and the differential signal pads Db+ and Db− are located in different columns and rows. In other words, the projections of the two adjacent differential signal pads Db+ and Db− on the X-axis or Y-axis do not overlap. A center extension line CL1 connecting two adjacent differential signal pads Da+ and Da− and a center extension line CL2 connecting two adjacent differential signal pads Db+ and Db− intersect at an intersection point IP. Further, the first pair of differential signal pads 110a and the second pair of differential signal pads 110b are symmetrically arranged with respect to a symmetry line SL. The intersection point IP of the center extension lines CL1 and CL2 is located on the symmetry line SL, but the center extension line CL1 or CL2 and the symmetry line SL are not perpendicular to each other. In addition, the arrangement of the first pair of differential signal pads 110a and the arrangement of the second pair of differential signal pads 110b are not parallel to the X-axis, nor are they parallel to the Y-axis. With respect to the X-Y coordinates and the symmetry line SL, the first pair of differential signal pads 110a and the second pair of differential signal pads 110b are inclined.

With reference to FIG. 2A and FIG. 2B, in this embodiment, the outer pads 111 may further include a plurality of reference pads. The reference pads are arranged around the pairs of differential signal pads 111 (D+/D−), and the reference pads are, for example, ground pads 111(G). As shown in FIG. 2A, each pair of differential signal pads 111 (D+/D−) is surrounded by eight ground pads 111(G), and the eight ground pads 111(G) are arranged in a hexagonal shape. To be more specific, a long side (the side where the three ground pads 111(G) are arranged in a line) of the hexagon is parallel to the center extension line CL1/CL2 of the corresponding pair of differential signal pads 111 (D+/D−), but is not parallel to the X-axis. The eighteen outer pads 111 of the first pad group 110-1 include one first pair of differential signal pads 110a, one second pair of differential signal pads 110b, and fourteen ground pads 111(G). Herein, the first pair of differential signal pads 110a and the second pair of differential signal pads 110b share two ground pads 111(G) at a junction area, and the two shared ground pads 111(G) are located on the symmetry line SL. Similarly, the eighteen outer pads 111 of the second pad group 110-2 include one first pair of differential signal pads 110a, one second pair of differential signal pads 110b, and fourteen ground pads 111(G) as well. The first pad group 110-1 and the second pad group 110-2 share two ground pads 111(G) at a junction area, and the two shared ground pads 111(G) are located on the symmetry line SL. The first pad group 110-1 and the second pad group 110-2 are symmetrical to each other with respect to the symmetry line SL. In addition, with respect to the X-Y coordinates and the symmetry line SL, the first pad group 110-1 and the second pad group 110-2 are inclined.

With reference to FIG. 1 and FIG. 2B, in this embodiment, the circuit board 100 may have a plurality of patterned conductive layers 101 and a plurality of conductive vias 102. The patterned conductive layers 101 are sequentially arranged and spaced apart below the mounting surface 100a. Each of the conductive vias 102 connects at least two patterned conductive layers 101. The patterned conductive layers 101 may include an outer circuit layer L1 and a first inner circuit layer L3. The outer circuit layer L1 and the first inner circuit layer L3 are sequentially arranged and spaced apart below the mounting surface 100a. The patterned conductive layers 101 may further include a first reference plane layer L2. The first reference plane layer L2 is disposed between the outer circuit layer L1 and the first inner circuit layer L3. The conductive vias 102 may pass through the first reference plane layer L2 to connect the outer circuit layer L1 and the first inner circuit layer L3.

With reference to FIG. 2A and FIG. 2B, in this embodiment, the outer circuit layer L1 has the outer pads 111. The first pair of differential signal pads 110a and the second pair of differential signal pads 110b of the first pad group 110-1 in the outer circuit layer L1 are sequentially arranged in a trace direction T perpendicular to the symmetry line SL, where the trace direction T is parallel to the X-axis, and the symmetry line SL is parallel to the Y-axis. The first inner circuit layer L3 has a plurality of first inner pads 121 and a plurality of first inner traces 122. The arrangement of the first inner pads 121 in the first inner circuit layer L3 is similar to the arrangement of the outer pads 111 in the outer circuit layer L1. The first inner pads 121 of the first inner circuit layer L3 are configured corresponding to the outer pads 111 of the outer circuit layer L1. Projections of part of the first inner pads 121 of the first inner circuit layer L3 on the outer circuit layer L1 overlap the outer pads 111 in the outer circuit layer L1. The pair of first inner traces 122a connected to one pair of first inner pads 121a (first inner pads 121a-1 and 121a-2) electrically connected to the first pair of differential signal pads 110a extends in the trace direction T and bypasses one pair of first inner pads 121b (first inner pads 121b-1 and 121b-2) electrically connected to the second pair of differential signal pads 110b. In other words, this pair of first inner traces 122a extending from the pair of first inner pads 121a does not pass between the first inner pad 121b-1 and the first inner pad 121b-2 when extending in the trace direction T, but passes from the outer sides of the first inner pad 121b-1 and the first inner pad 121b-2. Similarly, when the pair of first inner traces 122b extending from the pair of first inner pads 121b (first inner pads 121b-1 and 121b-2) extends in the trace direction T, the pair of first inner traces 122b does not pass between the first inner pad 121a-1 and the first inner pad 121a-2 electrically connected to the first pair of differential signal pads 110a of the second pad group 110-2, but passes from the outer sides of the pair of first inner pads 121a-1 and 121a-2. To be more specific, a pair of inner traces 122a or 122b connected to a corresponding pair of inner pads (121a or 121b) in the first inner circuit layer L3 extend in the trace direction T and bypass the inner pads (121a or 121b) electrically connected to the remaining pairs of differential signal pads (110a or 110b), so as to prevent the pair of inner traces from interfering with the differential signal pads.

With reference to FIG. 1, FIG. 2A and FIG. 2B, in this embodiment, the patterned conductive layers 101 may further include a second inner circuit layer L5. The outer circuit layer L1, the first inner circuit layer L3, and the second inner circuit layer L5 are sequentially arranged and spaced apart below the mounting surface 100a. The patterned conductive layers 101 may further include a second reference plane layer LA. The second reference plane layer L4 is disposed between the first inner circuit layer L3 and the second inner circuit layer L5. The conductive vias 102 may pass through the second reference plane layer LA to connect the first inner circuit layer L3 and the second inner circuit layer L5.

With reference to FIG. 2A and FIG. 2B, in this embodiment, the first pair of differential signal pads 110a and the second pair of differential signal pads 110b of the second pad group 110-2 in the outer circuit layer L1 are arranged sequentially in the trace direction T, where the trace direction T is parallel to the X-axis, and the symmetry line SL is parallel to the Y-axis. The second inner circuit layer L5 has a plurality of second inner pads 131 and a plurality of second inner traces 132. The arrangement of the second inner pads 131 in the second inner circuit layer L5 is similar to the arrangement of the outer pads 111 in the outer circuit layer L1. The second inner pads 131 of the second inner circuit layer L5 are configured corresponding to the outer pads 111 of the outer circuit layer L1 and the first inner pads 121 of the first inner circuit layer L3. Projections of part of the second inner pads 131 in the second inner circuit layer L5 on the outer circuit layer L1 overlap the projections of the first inner pads 121 in the first inner circuit layer L3 on the outer circuit layer L1. The pair of second inner traces 132a connected to one pair of second inner pads 131a (second inner pads 131a-1 and 131a-2) electrically connected to the first pair of differential signal pads 110a of the second pad group 110-2 extends in the trace direction T and bypasses one pair of second inner pads 131b (second inner pads 131b-1 and 131b-2) electrically connected to the second pair of differential signal pads 110b of the second pad group 110-2. In other words, this pair of second inner traces 132a extending from the pair of second inner pads 131a does not pass between the second inner pad 131b-1 and the second inner pad 131b-2 when extending in the trace direction T, but passes from the outer sides of the second inner pad 131b-1 and the second inner pad 131b-2. Similarly, this pair of second inner traces 132b extending from the pair of second inner pads 131b does not pass between the second inner pad 131a-1 and the second inner pad 131a-2 (not shown) electrically connected to the next pad group (not shown) when extending in the trace direction T, but passes from the outer sides of this pair of second inner pads 131a-1 and 131a-2 (not shown). To be more specific, a pair of inner traces 132a or 132b connected to a corresponding pair of inner pads (131a or 131b) in the second inner circuit layer L5 extend in the trace direction T and bypass the paired inner pads (131a or 131b) electrically connected to the remaining pairs of differential signal pads (110a or 110b), so as to prevent the pair of inner traces from interfering with the differential signal pads.

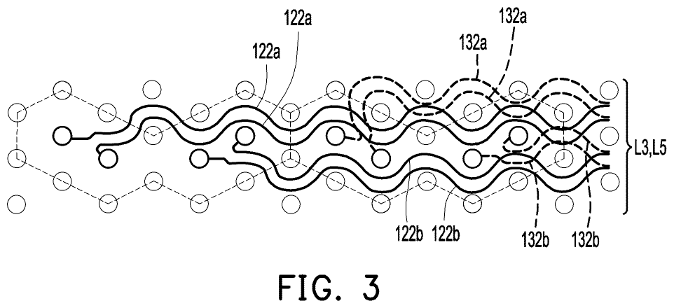

With reference to FIG. 1, FIG. 2B and FIG. 3, it can be seen from this embodiment that the outer pads 111 and the inner pads 121 in the same layer are staggered. Further, when extending in the trace direction T, the pairs of inner traces 122a, 122b, 132a and 132b bypass the other pairs of differential signal pads. Therefore, the orthographic projections of the first pairs of inner traces 122a and 122b on the mounting surface 100a and the orthographic projections of the second pairs of inner traces 132a and 132b on the mounting surface 100a only partially overlap. In this way, the mutual interference between the traces and pads on different circuit layers may also be reduced.

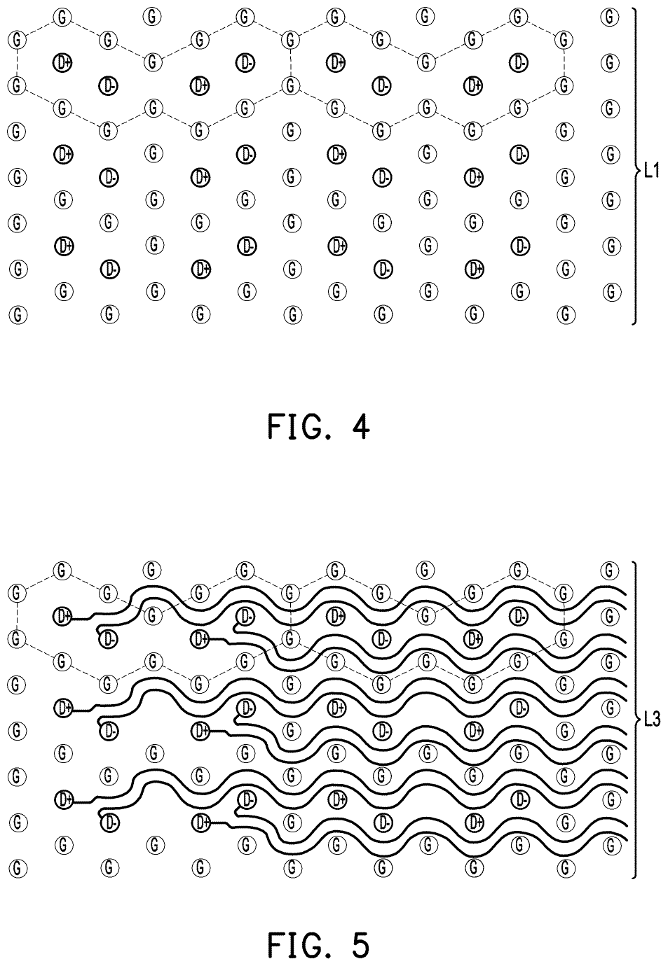

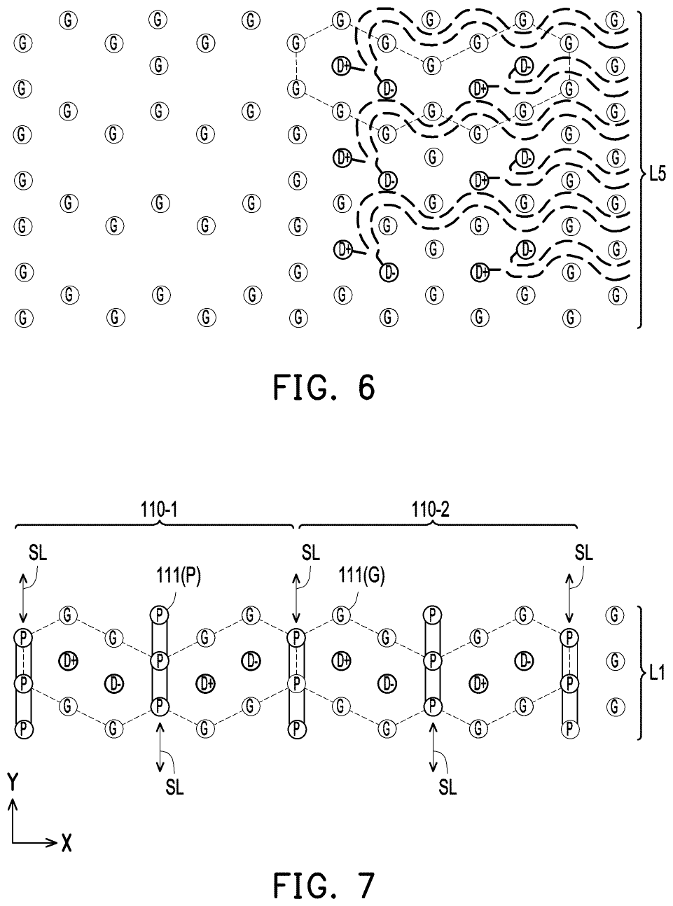

With reference to FIG. 4, FIG. 5 and FIG. 6, in this embodiment, a layout of the outer circuit layer L1 in FIG. 2B may be repeatedly expanded on the same plane, as shown in FIG. 4. A layout of the first inner circuit layer L3 in FIG. 2B may be repeatedly expanded on the same plane, as shown in FIG. 5. A layout of the second inner circuit layer L5 in FIG. 2B may be repeatedly expanded on the same plane, as shown in FIG. 6. It can be seen from these figures, the arrangement of the inner pads 121 in the first inner circuit layer L3 or the inner pads 131 in the second inner circuit layer L5 is similar to the arrangement of the outer pads 111 in the outer circuit layer L1. The projections of part of the inner pads 121 in the first inner circuit layer L3 or the inner pads 131 in the second inner circuit layer L5 on the outer circuit layer L1 overlap the outer pads 111 in the outer circuit layer L1.

With reference to FIG. 7, in another embodiment, the reference pads on the symmetry line SL may also be power pads 111 (P) instead of the original ground pads 111(G). The remaining reference pads of the first pad group 110-1 or the second pad group 110-2 are still the ground pads 111(G). In this embodiment, at least two adjacent power pads 111(P) parallel to the Y-axis may be electrically connected to each other, so as to act as a reference power source for a high-speed signal to avoid resonance within an operating frequency range. In addition, the pairs of differential signal pads 111 (D+/D−) respectively located on both sides of the symmetry line SL share the power pads 111 (P) on the symmetry line SL. Besides, in this embodiment, the power pads 111 (P) of the same layer (i.e., constructed from portions of the same patterned conductive layer 101 (L1) as shown in FIG. 1) may be electrically connected to each other first, and then transmitted to other patterned conductive layers 101 (L3, L5, . . . , etc.) through the conductive vias 102 as shown in FIG. 1 to improve the quality of power transmission.

With reference to FIG. 8, in another embodiment, in addition to the circuit board 100 of FIG. 1, the electronic assembly 10 may further include a socket electrical connector 12 and a chip package 11. The socket electrical connector 12 is mounted on the mounting surface 100a of the circuit board 100 and has a plurality of flexible terminals 12a. The flexible terminals 12a are soldered to the outer pad pads 111 of the circuit board 100 respectively. The chip package 11 is mounted on the socket electrical connector 12 and has a plurality of package pads 11b. The flexible terminals 12a are in flexible contact with the package pads 11b respectively.

With reference to FIG. 9, in another embodiment, in addition to the circuit board 100 of FIG. 1, the electronic assembly 10 may further include a chip package 11 and a plurality of conductive balls 13. The chip package 11 has a package surface 11a and a plurality of package pads 11b. The conductive balls 13 connect the package pads 11b to the outer pads 111 respectively.

In view of the foregoing, in the disclosure, the circuit board may provide a layout for differential signal transmission, and the center extension lines of two adjacent pairs of differential signal pads are inclined and intersect each other. Further, by arranging two adjacent pairs of differential signal pads in an inclined manner, the traces below may be prevented from passing through the same pair of differential signal pads, so that the problem of signal interference is solved. Further, by replacing part of the ground pads with power pads and electrically connecting adjacent power pads to each other, they can be used as reference power for a high-speed signal to avoid resonance within the operating frequency range.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic assembly, comprising:
a circuit board having a mounting surface and a plurality of outer pads located on the mounting surface and staggered, wherein the outer pads comprise a plurality of pairs of differential signal pads arranged adjacent to each other, the pairs of differential signal pads comprise a first pair of differential signal pads and a second pair of differential signal pads, the first pair of differential signal pads and the second pair of differential signal pads are symmetrically arranged with respect to a symmetry line, a center extension line passing through the first pair of differential signal pads and a center extension line passing through the second pair of differential signal pads intersect at an intersection point on the symmetry line, and the center extension line passing through the first pair of differential signal pads or the center extension line passing through the second pair of differential signal pads and the symmetry line are not perpendicular to each other.

2. The electronic assembly according to claim 1, wherein the outer pads comprise a plurality of reference pads, and the reference pads are arranged around the pairs of differential signal pads.

3. The electronic assembly according to claim 2, wherein eighteen outer pads among the outer pads are grouped into a first pad group, the first pad group comprises the first pair of differential signal pads, the second pair of differential signal pads, and fourteen reference pads, and the first pair of differential signal pads and the second pair of differential signal pads respectively located on both sides of the symmetry line share the reference pads located on the symmetry line.

4. The electronic assembly according to claim 2, wherein the reference pads are ground pads, and the first pair of differential signal pads and the second pair of differential signal pads respectively located on both sides of the symmetry line share the ground pads located on the symmetry line.

5. The electronic assembly according to claim 2, wherein the reference pads on the symmetry line are power pads, and the remaining reference pads are ground pads.

6. The electronic assembly according to claim 5, wherein the first pair of differential signal pads and the second pair of differential signal pads respectively located on both sides of the symmetry line share the power pads located on the symmetry line.

7. The electronic assembly according to claim 5, wherein the circuit board has a plurality of patterned conductive layers and a plurality of conductive vias, the patterned conductive layers are sequentially arranged and spaced apart below the mounting surface, each of the conductive vias connects at least two of the patterned conductive layers, and the power pads constructed from portions of the same patterned conductive layer are electrically connected to each other.

8. The electronic assembly according to claim 1, wherein the circuit board has a plurality of patterned conductive layers and a plurality of conductive vias, the patterned conductive layers are sequentially arranged and spaced apart below the mounting surface, each of the conductive vias connects at least two of the patterned conductive layers, the patterned conductive layers comprise an outer circuit layer and a first inner circuit layer, the outer circuit layer and the first inner circuit layer are sequentially arranged and spaced apart below the mounting surface, the outer circuit layer has the outer pads, the first inner circuit layer has a plurality of first inner pads and a plurality of first inner traces, the first pair of differential signal pads and the second pair of differential signal pads are arranged sequentially in a trace direction, and the first inner traces connected to the first inner pads electrically connected to the first pair of differential signal pads respectively extend in the trace direction and bypass the first inner pads electrically connected to the second pair of differential signal pads.

9. The electronic assembly according to claim 8, wherein part of the outer pads are grouped into a first pad group and a second pad group, each of the first pad group and the second pad group comprises the first pair of differential signal pads and the second pair of differential signal pads, and when extending from the first inner pads electrically connected to the first pair of differential signal pads of the first pad group extend in the trace direction, the first inner traces bypass the first inner pads electrically connected to the first pair of differential signal pads of the second pad group.

10. The electronic assembly according to claim 8, wherein part of the outer pads are grouped into a first pad group and a second pad group, each of the first pad group and the second pad group comprises the first pair of differential signal pads and the second pair of differential signal pads, and the patterned conductive layers comprise a second inner circuit layer, the outer circuit layer, the first inner circuit layer, and the second inner circuit layer are sequentially arranged and spaced apart below the mounting surface, the second inner circuit layer has a plurality of second inner pads and a plurality of second inner traces, the first pair of differential signal pads and the second pair of differential signal pads of the first pad group and the first pair of differential signal pads and the second pair of differential signal pads of the second pad group are arranged sequentially in the trace direction, and the second inner traces connected to the second inner pads electrically connected to the first pair of differential signal pads of the second pad group respectively extend in the trace direction and bypass the second inner pads electrically connected to the second pair of differential signal pads of the second pad group.

11. The electronic assembly according to claim 10, wherein orthographic projections on the mounting surface of the first inner traces connected to the first inner pads electrically connected to the first pair of differential signal pads of the first pad group respectively and orthographic projections on the mounting surface of the second inner traces connected to the second inner pads electrically connected to the first pair of differential signal pads of the second pad group respectively only partially overlap.

12. The electronic assembly according to claim 1, wherein the outer pads are in a form of a land grid array.

13. The electronic assembly according to claim 1, further comprising:
a socket electrical connector mounted on the mounting surface of the circuit board and having a plurality of flexible terminals, wherein the flexible terminals are soldered to the outer pad pads of the circuit board respectively; and
a chip package mounted on the socket electrical connector and having a plurality of chip pads, wherein the flexible terminals are in flexible contact with the chip pads respectively.

14. The electronic assembly according to claim 1, further comprising:
a chip package having a plurality of chip pads; and
a plurality of conductive balls connecting the chip pads to the outer pad pads respectively.
